(19) United States
(12) Patent Application Publication
(10) Pub. No.: US 2021/0305822 A1
(43) Pub. Date: Sep. 30, 2021

(54) CHARGING DEVICE AND METHOD THEREOF

(71) Applicant: Quanta Computer Inc., Taoyuan City (TW)

(72) Inventors: Chih-Hsiung YU, Taoyuan City (TW); Liang-Chia HUANG, Taoyuan City (TW); Wei-Ken TING, Taoyuan City (TW); Chia-Yin LAI, Taoyuan City (TW); Chia-Hsiu CHANG, Taoyuan City (TW)

(21) Appl. No.: 17/026,641

(22) Filed: Sep. 21, 2020

(30) Foreign Application Priority Data
Mar. 24, 2020 (TW) 109109723

(51) Int. Cl. H02J 7/00; G01R 31/327

(52) U.S. Cl. CPC H02J 7/0036; H02J 2207/30; H02J 7/00712; G01R 31/3274

(57) ABSTRACT

A charging device and method thereof is provided. The charging device is connected to a power supply device. The charging device includes a detection pin, a switch module, and a control circuit. The detection pin has a voltage level which reflects whether the charging device is connected to an electronic device. The control circuit is connected to the detection point and the switch module. According to the voltage level of the detection pin, the control module controls the switch module to be in an open state if the control circuit determines that the charging device is not connected to the electronic device.

### CROSS REFERENCE TO RELATED APPLICATIONS

This application claims priority of Taiwan Patent Application No. 109109723, filed on Mar. 24, 2020, the entirety of which is incorporated by reference herein.

### BACKGROUND OF THE INVENTION

### Field of the Invention

This invention relates to a charging device and method, and more particularly to a charging device and method for preventing leakage current from harming users.

### Description of the Related Art

Generally, medical apparatuses, accessories or facilities that physically touch a patient or that must be touched by the patient are required to meet specifications related to a specific leakage current value to prevent the leakage currents caused by the medical apparatuses, accessories or facilities from harming the patient. However, although there are strict specifications for leakage currents in medical apparatuses, if the medical apparatuses are required to be light, thin, and short, the charging bases corresponding to the medical apparatuses may need to expose its metal contacts to reduce the volume. Therefore, when the metal contacts of the medical apparatuses are exposed, how to ensure that the leakage currents meet the requirements in the specifications of the medical apparatuses is really a problem that needs to be solved today.

### BRIEF SUMMARY OF THE INVENTION

In view of this, the present invention proposes a charging device and a charging method thereof, which control the state of a plurality switches with a control circuit, so that when the charging device is not connected to an electronic device to be charged, the plurality of sets of switches are in an open state. A current provided by a power supply device cannot flow to metal contacts of a connection port of the charging device that users may touch, so as to achieve the effect of protecting the users.

An embodiment of the present invention provides a charging device. A first terminal of the charging device is connected to a power supply device through a universal serial bus port. The charging device comprises a detection contact, a switch module, and a control circuit. The detection contact has a voltage level which reflects whether a second terminal of the charging device is connected to an electronic device. A first terminal of the switch module is connected to the power supply device through the universal serial bus connection port. The control circuit is connected to the detection contact and the switch module. In response to the control circuit determining that the second terminal of the charging device is not connected to the electronic device according to the voltage level of the detection contact, the control circuit controls the switch module to be in an open state.

In an embodiment of the present invention, in response to the control circuit determining that the second terminal of the charging device has been connected to the electronic device according to the voltage level of the detection contact, the control circuit controls the switch module to be in an on state, such that the electronic device which a second terminal of the switch module is connected to obtains power provided by the power supply device.

In an embodiment of the present invention, the switch module comprises a first switch, and the first switch is disposed on a universal serial bus positive power line. In response to the first switch being in the on state, the universal serial bus positive power line provides a fixed voltage to the electronic device for charging the electronic device.

In an embodiment of the present invention, in response to the voltage level of the detection contact being a high level, the control circuit determines that the second terminal of the charging device is not connected to the electronic device.

In an embodiment of the present invention, the control circuit comprises a pull-up resistor connected to the detection contact. In response to the second terminal of the charging device being not connected to the electronic device, a current flowing through the pull-up resistor is less than 100 microamperes.

An embodiment of the present invention provides a charging method for a charging device A first terminal of the charging device is connected to a power supply device through a universal serial bus connection port, and a first terminal of a switch module in the charging device is connected to the power supply device through the universal serial bus connection port The charging method comprises steps of detecting a voltage level of a detection contact of the charging device to determine whether a second terminal of the charging device is connected to an electronic device; and using a control circuit. The control circuit is connected to the detection contact and the switch module. In response to the control circuit determining that the second terminal of the charging device is not connected to the electronic device according to the voltage level of the detection contact, the control circuit controls the switch module to be in an open state.

In an embodiment of the invention, the charging method further comprises a step of in response to the control circuit determining that the second terminal of the charging device has been connected to the electronic device according to the voltage level of the detection contact, controlling the switch module to be in an on state by using the control circuit, so that the electronic device which the second terminal of the switch module is connected to obtains power provided by the power supply device.

In an embodiment of the present invention, wherein the switch module comprises a first switch, and the first switch is disposed on a universal serial bus positive power line. In response to the first switch being in the on state, the universal serial bus positive power line provides a fixed voltage to the electronic device for charging the electronic device.

In an embodiment of the present invention, in response to the voltage level of the detection contact being a high level, the control circuit determines that the second terminal of the charging device is not connected to the electronic device.

In an embodiment of the present invention, the control circuit comprises a pull-up resistor, and a current flowing through the pull-up resistor is less than 100 microamperes.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawings, wherein:

FIG. 1 is a schematic diagram showing an exemplary embodiment of a charging device;

FIG. 2 is a flowchart of an exemplary embodiment of a charging method; and

FIG. 3 is a schematic diagram showing an exemplary embodiment of a charging device and an electronic device charged by the charging device.

### DETAILED DESCRIPTION OF THE INVENTION

In order to make the above and other objects, the features and advantages of the present invention more obvious and understandable, the preferred embodiments are specifically listed below by referring to the accompanying drawings and described in detail as follows. It should be noted that this section describes the best way to implement the present invention. The purpose is to illustrate the spirit of the present invention and not to limit the scope of protection of the present invention. It should be understood that the following embodiments can be implemented by software, hardware, firmware or any combination of the above.

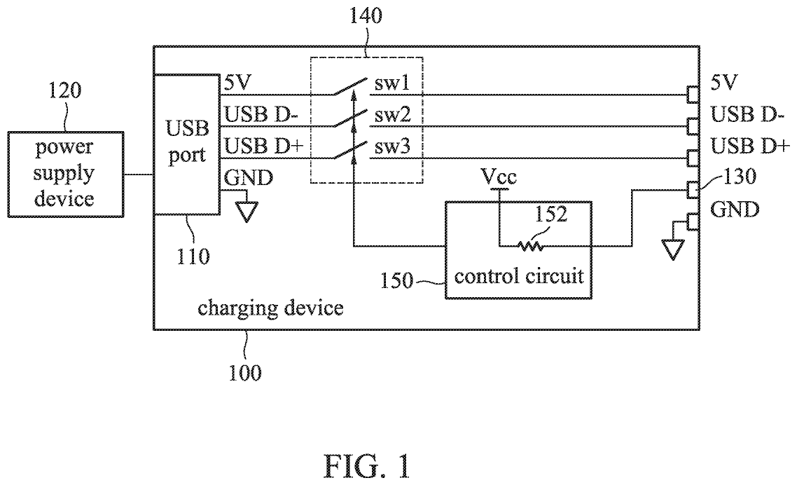

The present invention provides a charging device and a charging method thereof. FIG. 1 is a schematic diagram showing an exemplary embodiment of a charging device. The charging device is shown as 100 in FIG. 1.

The first terminal of the charging device 100 of the present invention is connected to a power supply device 120 through a universal serial bus (USB) port (hereinafter referred to as USB port) 110. In an embodiment of the present invention, the power supply device 120 may be composed of a supply mains source and a voltage transformer element. In other words, the alternating-current voltage provided by the supply mains is converted by the voltage transformer element to a direct-current (DC) voltage, and then the DC voltage is provided to the charging device 100.

As shown in FIG. 1, the USB port comprises four pins. Among the four pins, two pins are used for data transmission, and the other two pins are used as power line contacts for charging.

In detail, the lines connected to the two pins used for data transmission are a universal serial bus negative voltage data line (USB D−) of the in FIG. 1 and a universal serial bus positive voltage data line (USB D+). The lines connected to the power line contacts for charging are a universal serial bus positive power line in FIG. 1 (such as 5V in FIG. 1) and a universal serial bus ground power line in FIG. 1 (such as GND in FIG. 1).

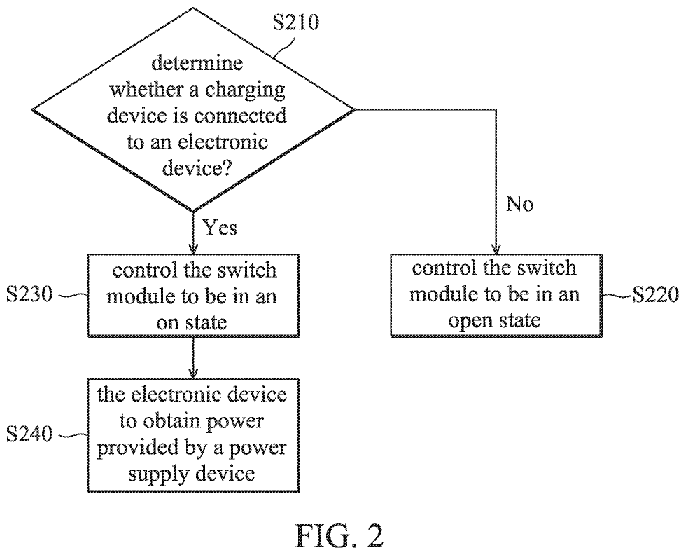

As shown in FIG. 1, the charging device 100 comprises a detection contact 130, a switch module 140, and a control circuit 150. As described above, the first terminal of the charging device 100 is connected to the power supply device 120 through the USB port 110. The detection contact 130 may be a metal pin with a voltage level. FIG. 2 is a flowchart of an exemplary embodiment of a charging method. Please refer to FIGS. 1 and 2 at the same time. The voltage level of the detection contact 130 is detected to reflect whether another terminal (such as a second terminal) of the charging device 100 is connected to an electronic device 160 (step S210), so that the control circuit 130 can determine whether the charging device 100 is connected to the electronic device 160 according to the voltage level of the detection contact 130.

A first terminal of the switch module 140 is connected to the power supply device 120 through the USB port 110. The switch module 140 comprises a first switch SW1, a second switch SW2, and a third switch SW3. In an embodiment, the switches SW1, SW2, and SW3 are implemented by general electronic switch elements.

The first switch SW1 is disposed on the positive power line (5V) of the universal serial bus. The second switch SW2 is disposed on the universal serial bus negative voltage data line (USB D−), and the third switch SW3 is disposed on the universal serial bus positive voltage data line (USB D−).

The control circuit 150 of the charging device 100 is connected to the detection contact 130 and the switch module 140. The control circuit 150 detects the voltage level of the detection contact 130. When the voltage level of the detection contact 130 is a high level, the control circuit 150 determines that the second terminal of the charging device 100 is not connected to any electronic device (such as the electronic device 160) according to the voltage level of the detection contact 130. In other words, if the determination in Step S210 is negative, which indicates that the control circuit 150 determines that the second terminal of the charging device 100 is not connected to any electronic device 160, the control circuit 150 controls the switch module 140 to be in an open state (also referred to as “off state”) (Step S220). At this time, the first switch SW1, the second switch SW2, and the third switch SW3 are all in the open state. Therefore, when all three of the switches are in the open state, the currents respectively on the universal serial bus positive power line (5V), the universal serial bus negative voltage data line (USB D−), and the universal serial bus positive voltage data line (USB D+) are equal to 0 amps.

In short, in the above situation, when the charging device 100 is not connected to any electronic device 160 for charging, because the switch module 140 is in the open state, no currents flow through the metal contacts at the second terminal which are connected to the universal serial bus positive power line, the universal serial bus negative voltage data line (USB D−), and the universal serial bus positive voltage data line (USB D+) respectively. If users accidentally touch these metal contacts, they will not be harmed by currents.

It should be particularly noted that, in the embodiment of the present invention, the control circuit 150 determines whether the charging device 100 is currently connected to an electronic device 160 according to whether the detection contact 130 connected to the control circuit 150 is at a high voltage level or a low voltage level. To continuously perform the determination, the control circuit 150 needs power or power supply for itself. As shown in FIG. 1 of the embodiment of the present invention, the control circuit 150 is supplied by a stable direct-current (DC) voltage Vcc, which may be 5 volts in this embodiment. Therefore, in the case in which the charging device 100 is not connected to any electronic device 160, the metal pin used as the detection contact 130 is exposed, and the users may touch the detection contact 130 and suffer the leakage current. Therefore, in an embodiment of the present invention, a pull-up resistor 152 is disposed in the control circuit 150 and connected to the detection contact 130. The resistance value of the pull-up resistor 150 has to be higher than a specific value, so that the current flowing through the pull-up resistor 152 can be within a safe range lower than 100 microamperes.

On the contrary, when the control circuit 150 determines that the second terminal of the charging device 100 has been connected to an electronic device 160 according to the voltage level of the detection contact 130, the control circuit 150 controls the switch module 140 to be in an on state (Step S230).

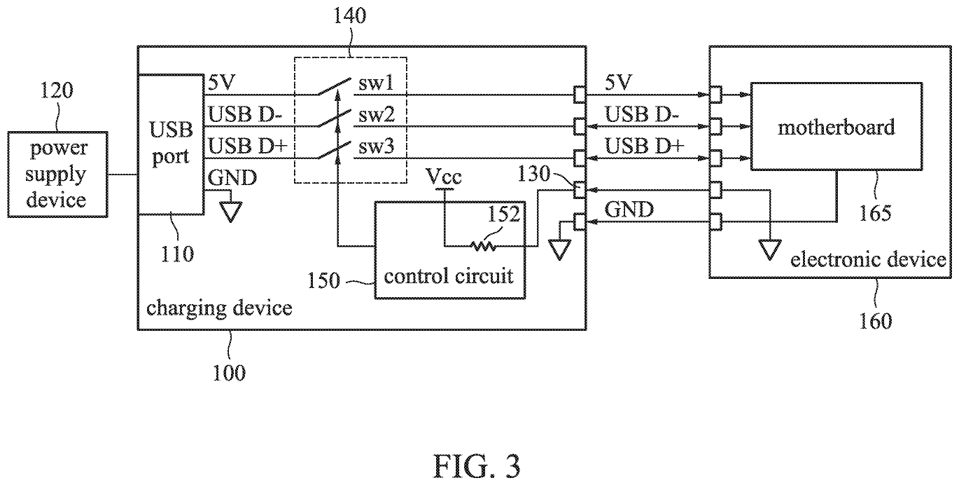

In detail, as shown in FIG. 3, FIG. 3 is a schematic diagram shows that the charging device charges an electronic device according to an embodiment of the present invention. When the charging device 100 is connected to the electronic device 160, the detection contact 130 is coupled to the ground through the electronic device 160. At this time, according to the ground state of the detection contact 130, the control circuit 150 connected to the detection contact 130 determines that the charging device 100 is currently connected to the electronic device 160, and the control circuit 150 controls the first switch SW1, the second switch SW2, and the third switch SW3 of the switch module 140 to be turned on.

According to the above description, since the switch module 140 is in the on state, the electronic device 160 connected to the second terminal of the switch module 140 can obtain the power provided by the power supply device 120 through the turned-on switch module 140 in the charging device 100 (Step S240). More specifically, when the first switch SW1 is in the on state, the universal serial bus positive power line (5V) provides a fixed voltage to the electronic device 160 and charge it, to that the motherboard 165 of the electronic device 160 is enabled.

In other embodiments of the present invention, the power supply device 120 may be composed of a computer device having a power supply and a voltage transformer element. At this time, the electronic device 160 can not only be charged by the charging device 100, but also perform data transmission. For example, the supply mains is provided through a universal serial bus slot of the computer device. When the control circuit 150 determines that the charging device 100 is connected to the electronic device 160 according to the voltage level of the detection contact 130 based on the aforementioned process, the control circuit 150 controls the switch module 140 to be the on state, so that the electronic device 160 connected to the charging device 100 can obtain the data provided by the computer device through the turned-on switches.

In a specific embodiment, the electronic device 160 comprises a medical apparatus.

In summary, the core concept of the charging device and the charging method proposed by the present invention is to use a control circuit to control states of a plurality of switches. Based on the operation of the control circuit, when the charging device is not connected to the electronic device to be charged, the plurality of switches are in an open state. Thus, a current provided by a power supply device cannot flow to the metal contacts of the connection port of the charging device port that the user may touch, thereby achieving the effect of protecting the users.

While the invention has been described by way of example and in terms of the preferred embodiments, it is to be understood that the invention is not limited to the disclosed embodiments. On the contrary, it is intended to cover various modifications and similar arrangements (as would be apparent to those skilled in the art). For example, the system and method described in the embodiments of the present invention may be implemented by physical embodiments of hardware, software, or a combination of hardware and software. Therefore, the scope of the appended claims should be accorded the broadest interpretation so as to encompass all such modifications and similar arrangements.

What is claimed is:

1. A charging device, a first terminal of the charging device connected to a power supply device through a universal serial bus port, the charging device comprising:
a detection contact having a voltage level which reflects whether a second terminal of the charging device is connected to an electronic device;
a switch module, wherein a first terminal of the switch module is connected to the power supply device through the universal serial bus connection port; and
a control circuit connected to the detection contact and the switch module, wherein in response to the control circuit determining that the second terminal of the charging device is not connected to the electronic device according to the voltage level of the detection contact, the control circuit controls the switch module to be in an open state.

2. The charging device as claimed in claim 1, wherein in response to the control circuit determining that the second terminal of the charging device has been connected to the electronic device according to the voltage level of the detection contact, the control circuit controls the switch module to be in an on state, such that the electronic device which a second terminal of the switch module is connected to obtains power provided by the power supply device.

3. The charging device as claimed in claim 2,
wherein the switch module comprises a first switch, and the first switch is disposed on a universal serial bus positive power line, and
wherein in response to the first switch being in the on state, the universal serial bus positive power line provides a fixed voltage to the electronic device.

4. The charging device as claimed in claim 1, wherein in response to the voltage level of the detection contact being a high level, the control circuit determines that the second terminal of the charging device is not connected to the electronic device.

5. The charging device as claimed in claim 4, wherein the control circuit comprises a pull-up resistor connected to the detection contact, and in response to the second terminal of the charging device being not connected to the electronic device, a current flowing through the pull-up resistor is less than 100 microamperes.

6. A charging method for a charging device, wherein a first terminal of the charging device is connected to a power supply device through a universal serial bus connection port, a first terminal of a switch module in the charging device is connected to the power supply device through the universal serial bus connection port, and the charging method comprises:
detecting a voltage level of a detection contact of the charging device to determine whether a second terminal of the charging device is connected to an electronic device; and
using a control circuit, wherein the control circuit is connected to the detection contact and the switch module, and in response to the control circuit determining that the second terminal of the charging device is not connected to the electronic device according to the voltage level of the detection contact, the control circuit controls the switch module to be in an open state.

7. The charging method as claimed in claim 6, further comprising:
in response to the control circuit determining that the second terminal of the charging device has been connected to the electronic device according to the voltage level of the detection contact, controlling the switch module to be in an on state by using the control circuit, so that the electronic device which a second terminal of the switch module is connected to obtains power provided by the power supply device.

8. The charging method as claimed in claim 7,
wherein the switch module comprises a first switch, and the first switch is disposed on a universal serial bus positive power line, and
wherein in response to the first switch being in the on state, the universal serial bus positive power line provides a fixed voltage to the electronic device for charging the electronic device.

9. The charging method as claimed in claim 6, wherein in response to the voltage level of the detection contact being a high level, the control circuit determines that the second terminal of the charging device is not connected to the electronic device.

10. The charging method as claimed in claim 6, wherein the control circuit comprises a pull-up resistor, and a current flowing through the pull-up resistor is less than 100 microamperes.
